(19) United States
(12) Patent Application Publication
(10) Pub. No.: US 2024/0267007 A1
(43) Pub. Date: Aug. 8, 2024

(54) CLASS D AMPLIFICATION CIRCUIT

(71) Applicant: Murata Manufacturing Co., Ltd., Nagaokakyo-shi (JP)

(72) Inventor: Ryota KARAYA, Nagaokakyo-shi (JP)

(21) Appl. No.: 18/616,238

(22) Filed: Mar. 26, 2024

Related U.S. Application Data
(63) Continuation of application No. PCT/JP2023/032096, filed on Sep. 1, 2023.

(30) Foreign Application Priority Data
Nov. 24, 2022 (JP) 2022-187418

(51) Int. Cl. H03F 3/217; H04R 3/04

(52) U.S. Cl. CPC H03F 3/217; H04R 3/04; H03F 2200/03; H03F 2200/171

(57) ABSTRACT

A class D amplification circuit includes a low-pass filter circuit including an inductor, first and second capacitors, an input terminal, a first potential terminal, a second potential terminal, and an output terminal. The input terminal is connected to a drive circuit. The first potential terminal is connected to a first potential. The second potential terminal is connected to a second potential that is lower than the first potential. The output terminal is connected to a load circuit. One external electrode of the first capacitor is connected to the first potential terminal. One external electrode of the second capacitor is connected to the second potential terminal. Another external electrode of the first capacitor and another external electrode of the second capacitor are connected to the output terminal. One external electrode of the inductor is connected to the input terminal. Another external electrode of the inductor is connected to the output terminal.

### CROSS REFERENCE TO RELATED APPLICATIONS

This application claims the benefit of priority to Japanese Patent Application No. 2022-187418 filed on Nov. 24, 2022 and is a Continuation Application of PCT Application No. PCT/JP2023/032096 filed on Sep. 1, 2023. The entire contents of each application are hereby incorporated herein by reference.

### BACKGROUND OF THE INVENTION

### 1. Field of the Invention

The present invention relates to class D amplification circuits.

### 2. Description of the Related Art

Class D amplification circuits that amplify, for example, a sound signal and output the same to a load such as a speaker are known. For example, Japanese Unexamined Patent Application, Publication No. 2007-180695 describes a class D amplification circuit based on a PWM scheme. The class D amplification circuit includes a PWM circuit, a drive circuit, and a low-pass filter. The PWM circuit outputs a pulse-width modulated signal. The drive circuit amplifies the pulse-width modulated signal and outputs the amplified pulse-width modulated signal. The low-pass filter circuit removes the high frequency components of the amplified pulse-width modulated signal so as to output an analog sound signal. The low-pass filter circuit includes an inductor and a capacitor. The output analog sound signal is supplied to a load. Assuming that the analog signal represents a sound and the load is a speaker, the load generates the sound represented by the analog signal.

### SUMMARY OF THE INVENTION

The capacitance of a capacitor forming the low-pass filter circuit of a class D amplification circuit varies according to a voltage applied to the capacitor. Upon the capacitance of the capacitor varying according to the applied voltage, the cut-off frequency of the low-pass filter varies according to pulses. Varying the cut-off frequency of the low-pass filter may prevent a sound signal output to an output terminal from having desired characteristics. Accordingly, example embodiments of the present invention address the challenge to provide a class D amplification circuit that is capable of outputting an output signal having desired characteristics even when the voltage of a signal input to a capacitor of a low-pass filter changes.

A class D amplification circuit according to an example embodiment of the present invention includes a PWM circuit, a drive circuit connected to the PWM circuit, and a low-pass filter circuit connected to the drive circuit, wherein the low-pass filter circuit includes an inductor, a first capacitor, and a second capacitor, the first capacitor and the second capacitor each include a dielectric body and electrodes with the dielectric body therebetween, the low-pass filter circuit includes an input terminal, a first potential terminal, a second potential terminal, and an output terminal, the input terminal is connected to the drive circuit, the first potential terminal is connected to a first potential, the second potential terminal is connected to a second potential that is lower than the first potential, the output terminal is connected to a load circuit, one external electrode of the first capacitor is connected to the first potential terminal, one external electrode of the second capacitor is connected to the second potential terminal, another external electrode of the first capacitor and another external electrode of the second capacitor are connected to the output terminal, one external electrode of the inductor is connected to the input terminal, and another external electrode of the inductor is connected to the output terminal.

Example embodiments of the present invention provide class D amplification circuits each capable of outputting an output signal having desired characteristics even when the voltage of a signal input to a capacitor of a low-pass filter changes.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 illustrates a class D amplification circuit according to an example embodiment of the present invention.

FIG. 2 illustrates terminals of an inductor and capacitors according to an example embodiment of the present invention.

FIG. 3 illustrates a relationship between a voltage applied to a capacitor and the capacitance of the capacitor.

FIG. 4 illustrates a potential difference and the like provided when a signal is input to a low-pass filter circuit according to an example embodiment of the present invention.

FIG. 5 illustrates a conventional class D amplification circuit.

FIG. 6 illustrates a situation attained when a signal is input to a conventional low-pass filter circuit.

FIG. 7 is a perspective view illustrating a four-terminal multilayer ceramic capacitor according to an example embodiment of the present invention.

FIG. 8 illustrates at least portions of internal electrodes according to an example embodiment of the present invention.

FIG. 9 illustrates the circuit configuration of a low-pass filter circuit according to an example embodiment of the present invention.

FIG. 10 is a I-I line cross-sectional view of FIG. 7.

FIG. 11 is a II-II line cross-sectional view of FIG. 7.

FIG. 12 is a III-III line cross-sectional view of FIG. 7 that illustrates a plane structure of a first internal electrode 10a.

FIG. 13 is a III-III line cross-sectional view of FIG. 7 that illustrates a plane structure of a second internal electrode 10b.

FIG. 14 is a III-III line cross-sectional view of FIG. 7 that illustrates a plane structure of a third internal electrode 10c.

FIG. 15 illustrates a class D amplification circuit according to another example embodiment of the present invention.

FIG. 16 illustrates a potential difference and the like provided when a signal is input to a differential-signal filter circuit according to another example embodiment of the present invention.

### DETAILED DESCRIPTION OF THE EXAMPLE EMBODIMENTS

### First Example Embodiment

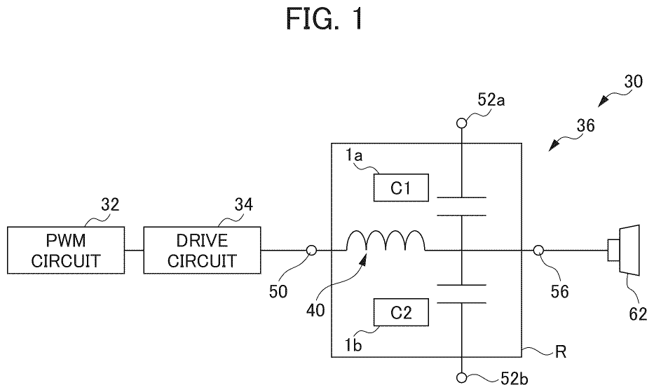

The following describes example embodiments of the present invention on the basis of the drawings. FIG. 1 illustrates the overview of a class D amplification circuit 30 according to an example embodiment of the present invention.

### Overview of Class D Amplification Circuit

The class D amplification circuit 30 according to the present example embodiment includes a PWM circuit 32, a drive circuit 34 connected to the PWM circuit 32, and a low-pass filter circuit 36 connected to the drive circuit 34. As indicated above, the PWM circuit 32 outputs a pulse-width modulated signal. The drive circuit 34 amplifies the pulse-width modulated signal and outputs the amplified pulse-width modulated signal. The low-pass filter circuit 36 removes high frequency components of the amplified pulse-width modulated signal.

### Overview of Low-Pass Filter Circuit

The low-pass filter circuit 36 includes an inductor 40 and capacitors 1. A load circuit 62 is connected to the low-pass filter circuit 36. A signal output from the low-pass filter circuit 36 is input to the load circuit 62.

Specifically, the low-pass filter circuit 36 includes an inductor 40 and at least two capacitors 1. The two capacitors 1 are a first capacitor 1a and a second capacitor 1b. In FIG. 1, C1 denotes the first capacitor 1a. C2 denotes the second capacitor 1b.

Each of the capacitors 1 includes a dielectric body and electrodes with the dielectric body therebetween. Thus, the capacitors 1 may define a lumped-constant circuit such as a multilayer ceramic capacitor or a film capacitor.

### Terminals of Low-Pass Filter Circuit

The low-pass filter circuit 36 includes four external terminals. The four external terminals are an input terminal 50, a first potential terminal 52a, a second potential terminal 52b, and an output terminal 56. The input terminal 50 is connected to the drive circuit 34. The first potential terminal 52a is connected to a first potential. The second potential terminal is connected to a second potential. The output terminal 56 is connected to the load circuit 62. For example, the first potential may be a power-supply voltage potential. For example, the second potential may be a ground (GND) potential.

Connections within Low-Pass Filter Circuit

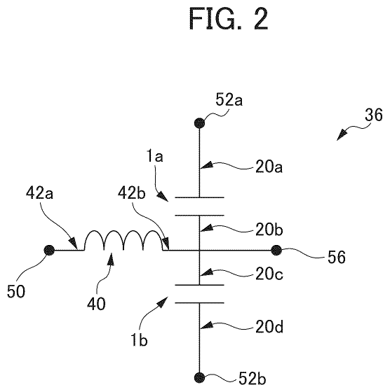

By referring to FIG. 2, descriptions are given of, for example, the connections of terminals of the inside of the low-pass filter circuit 36. FIG. 2 illustrates terminals of the inductor 40 and the capacitors 1. The inductor 40 includes two inductor external electrodes 42. One of the inductor external electrodes 42 is a first inductor external electrode 42a, and the other is a second inductor external electrode 42b. The first inductor external electrode 42a is connected to the input terminal 50. The second inductor external electrode 42b is connected to the output terminal 56.

Descriptions are given of the connection of the capacitors 1. The first capacitor 1a and the second capacitor 1b each include two external electrodes 20. One of the external electrodes 20 of the first capacitor 1a is an external electrode (A)20a, and the other is an external electrode (B)20b. The external electrode (A)20a is connected to the first potential terminal 52a. The external electrode (B)20b is connected to the output terminal 56.

Next, descriptions are given of the second capacitor 1b. One of the external electrodes 20 of the second capacitor 1b is an external electrode (D)20d, and the other is an external electrode (C)20c. The external electrode (D)20d is connected to the second potential terminal 52b. The external electrode (C)20c is connected to the output terminal 56.

### Voltage and Capacitance

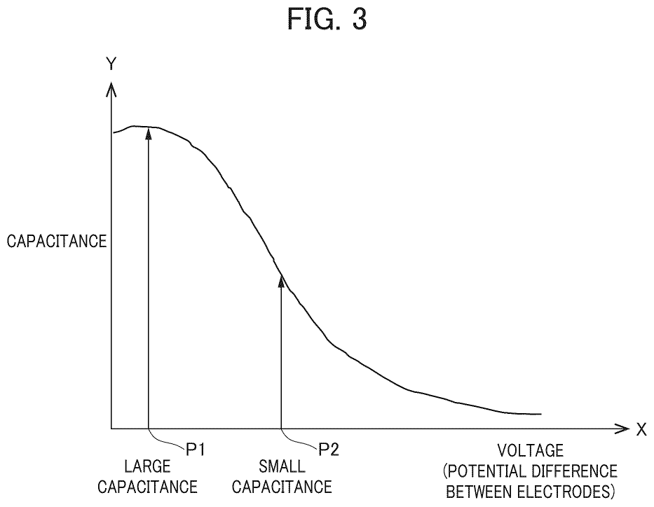

The class D amplification circuit 30 according to the present example embodiment has the above-described features and is thus capable of outputting an output signal having desired characteristics even when the voltage of a signal input to a capacitor 1 of the low-pass filter circuit 36 changes. In the following, descriptions are sequentially given. FIG. 3 illustrates a relationship between a voltage applied to a capacitor and the capacitance of the capacitor. The X axis in FIG. 3 indicates the voltage applied to the capacitor. The Y axis in FIG. 3 indicates the capacitance of the capacitor. The capacitance of the capacitor, which includes a dielectric body and electrodes with the dielectric body therebetween, changes according to the applied voltage. As indicated by a point P2 in FIG. 3, the capacitance of the capacitor is small when the voltage applied to the capacitor is relatively large. As indicated by a point P1 in FIG. 3, by contrast, the capacitance of the capacitor is large when the voltage applied to the capacitor is relatively small. Accordingly, the capacitance of the capacitor changes according to the voltage applied to the capacitor.

With respect to a class D amplification circuit that is provided with a low-pass filter circuit including capacitors that define a lumped-constant circuit, it is difficult to provide an output signal having desired characteristics if the capacitance of the capacitor varies according to the voltage of input pulses. This is because the cut-off frequency of the low-pass filter circuit varies according to the voltage of the input pulses.

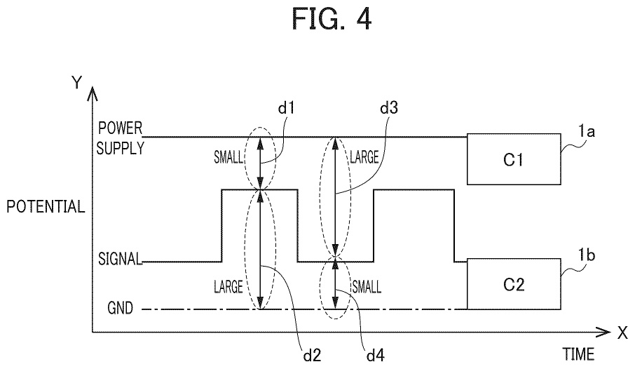

In this regard, the class D amplification circuit 30 according to the present example embodiment can output an output signal having desired characteristics even when the voltage of a signal input to a capacitor 1 of the low-pass filter circuit 36 changes. Descriptions are given in the following. FIG. 4 illustrates, for example, a voltage applied to each capacitor 1 when pulses are input to the class D amplification circuit 30 according to the present example embodiment. The X axis in FIG. 4 indicates time. The Y axis in FIG. 4 indicates potential.

When a pulse input to the low-pass filter circuit 36 is Hi, the voltage applied to C2, i.e., the second capacitor 1b, is large (d2 in FIG. 4). By contrast, the voltage applied to C1, i.e., the first capacitor 1a, is small (d1 in FIG. 4). Thus, “capacitance decrease of C2>capacitance decrease of C1” is satisfied. Conversely, when a pulse input to the capacitors 1 is L, the voltage applied to C1, i.e., the first capacitor 1a, is large (d3 in FIG. 4). By contrast, the voltage applied to C2, i.e., the second capacitor 1b, is small (d4 in FIG. 4). Thus, “capacitance decrease of C1>capacitance decrease of C2” is satisfied.

In the low-pass filter circuit 36 according to the present example embodiment, as described above, when the decrease in the capacitance of one capacitor from among C1 and C2 is large, the decrease in the capacitance of the other capacitor is small. This results in a reduction in the total capacitance of the entirety of the low-pass filter circuit 36 which varies according to pulses. Thus, variations in the cut-off frequency of the low-pass filter circuit 36 are reduced. Accordingly, desired characteristics can be easily achieved for an output signal output to the output terminal 56.

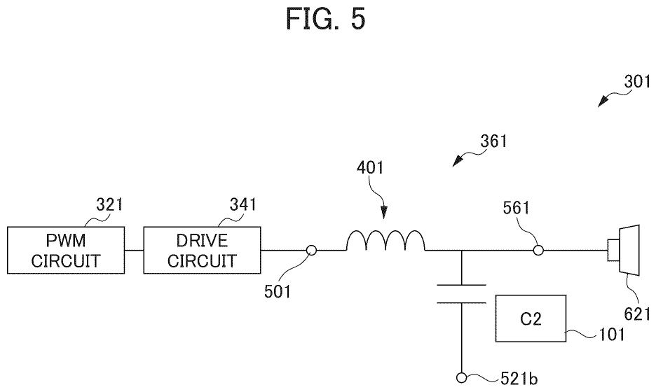

This fact can be more clearly understood through a comparison with a conventional class D amplification circuit. FIG. 5 illustrates a conventional class D amplification circuit 301. The conventional class D amplification circuit 301 includes a PWM circuit 321, a drive circuit 341, a low-pass filter circuit 361, and a load circuit 621. The low-pass filter circuit 361 includes an inductor 401 and a capacitor 101. In FIG. 5, C denotes the capacitor 101. One of the external electrodes of the inductor 401 is connected to an input terminal 501 of the low-pass filter circuit 361. The other external electrode of the inductor 401 is connected to an output terminal 561 of the low-pass filter circuit 361. The conventional low-pass filter circuit 361 includes only one capacitor. One of the external electrodes of the capacitor 101 is connected to a second potential terminal 521b. The potential of the second potential terminal 521b may be a ground (GND) potential. The other external electrode of the capacitor 101 is connected to the output terminal 561. The load circuit 621, such as a speaker, is connected to the output terminal 561.

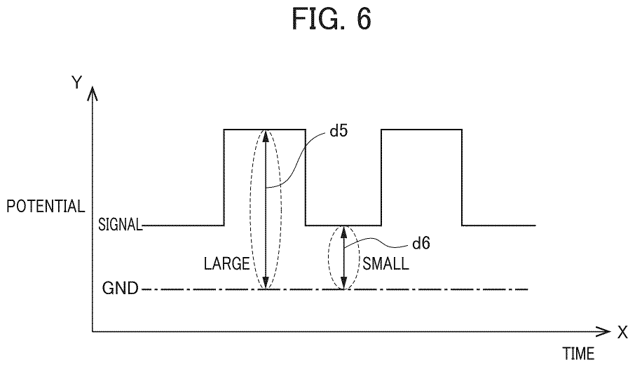

Assume that pulses are input to the input terminal 501 of the low-pass filter circuit 361 in the conventional class D amplification circuit 301 depicted in FIG. 5. FIG. 6 illustrates, for example, a voltage applied to the capacitor 101 when pulses are input to the conventional class D amplification circuit 301. When a pulse input to the low-pass filter circuit 36 is Hi, the voltage applied to C, i.e., the capacitor 101, is large (d5 in FIG. 6). When an input pulse is L, the voltage applied to C is small (d6 in FIG. 6). Thus, the capacitance of C is small when a pulse is Hi, and the capacitance of C is small when a pulse is L. Accordingly, the capacitance of the capacitor 101 of the conventional class D amplification circuit 301 changes according to a variation in the voltage of pulses. Upon the capacitance of the capacitor 101, i.e., C, varying according to pulses, the cut-off frequency of the low-pass filter circuit 361 varies according to the pulses. Varying the cut-off frequency of the low-pass filter circuit 361 may prevent, for example, a sound signal output to the output terminal 561 from having desired characteristics.

In the class D amplification circuit 30 according to the present example embodiment, by contrast, the low-pass filter circuit 36 includes two capacitors 1. Thus, even when the voltage of pulses input to the low-pass filter circuit 36 varies significantly, the influence on a signal output from the output terminal 56 can be reduced. For example, when the load circuit 62 connected to the output terminal 56 includes a speaker and a sound signal is output, desired and preferable sound output can be provided.

Values pertaining to the class D amplification circuit 30 according to the present example embodiment can be set as appropriate. Examples of the setting values may include: a value that is equal to about 50 kHz or higher and not higher than about 100 kHz as the cut-off frequency; about 7 uF as the electrostatic capacitance of C1, i.e., the first capacitor 1a; about 7 uF as the electrostatic capacitance of C2, i.e., the second capacitor; and about 500 nH as the inductance of the inductor 40. The capacitance ratio between the capacitors C1 and C2 may be within about ±50%, preferably within about ±10%, for example.

### Configuration of Capacitors

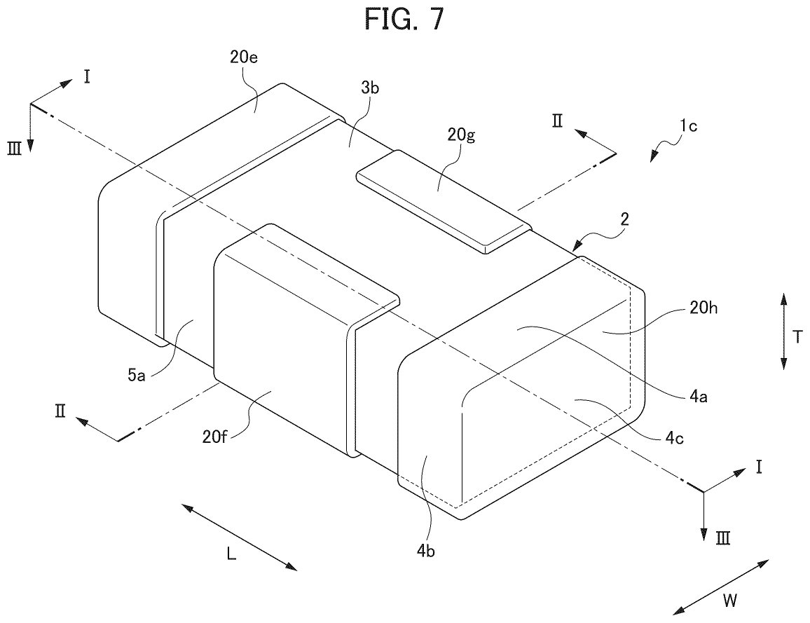

The following describes the configuration of the capacitors 1. The first capacitor 1a and the second capacitor 1b, i.e., the two capacitors 1 of the low-pass filter circuit 36, include one four-terminal multilayer ceramic capacitor 1c. First, the entire structure of the four-terminal multilayer ceramic capacitor 1c is described on the basis of FIG. 7.

### Outer Shape of Four-Terminal Multilayer Ceramic Capacitor

As depicted in FIG. 7, the four-terminal multilayer ceramic capacitor 1c includes a multilayer body 2 and external electrodes 20.

### Definitions of Directions

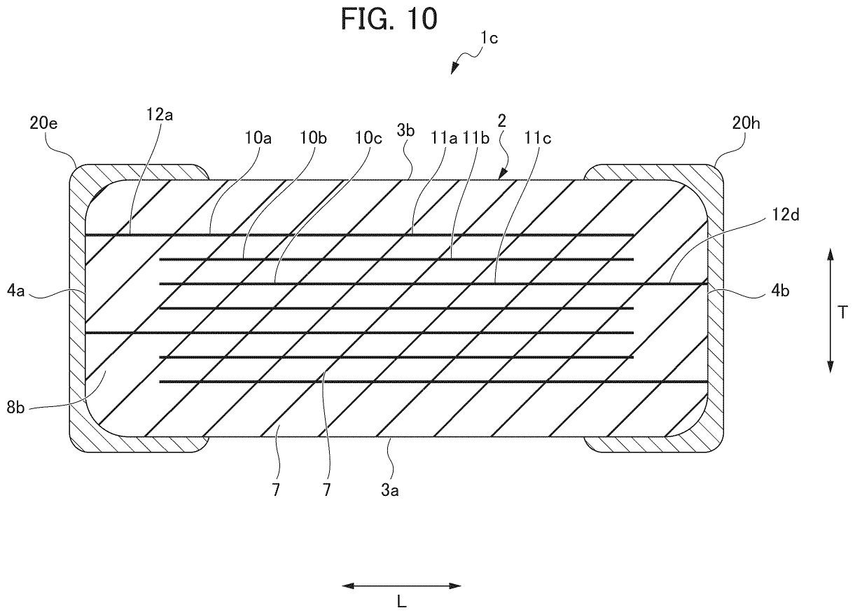

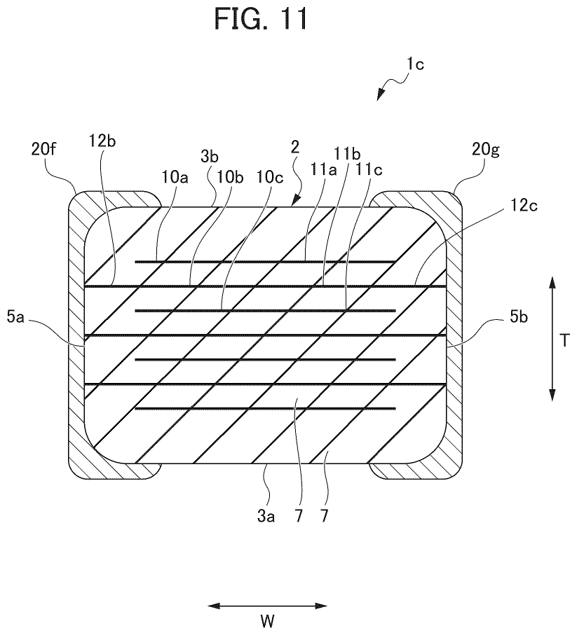

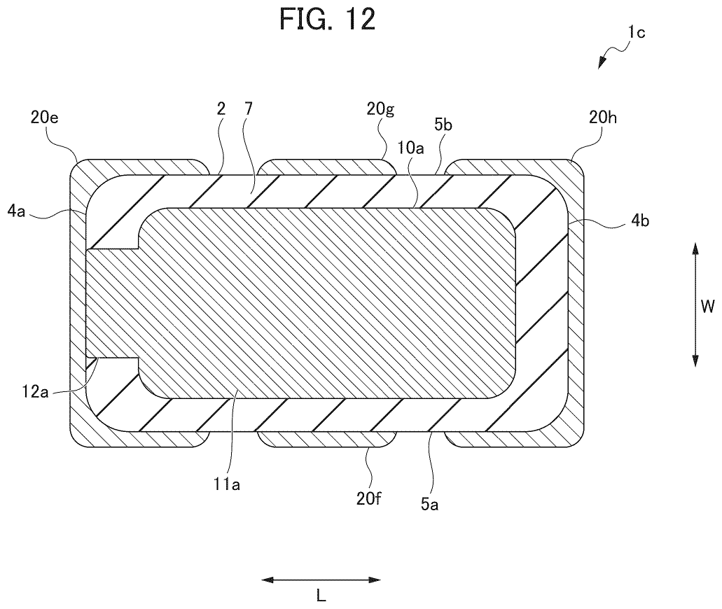

In the drawings, a L direction, a W direction, and a T direction are indicated as appropriate. The L direction is the length direction of the four-terminal multilayer ceramic capacitor 1c. The W direction is the width direction of the four-terminal multilayer ceramic capacitor 1c. The T direction is the height direction of the four-terminal multilayer ceramic capacitor 1c. Thus, the cross section depicted in FIG. 10 is referred to as a LT cross section, and the cross section depicted in FIG. 11 is referred to as a WT cross section. FIGS. 12, 13, and 14 are each referred to as a LW cross section. The length direction L, the width direction W, and the height direction T do not necessarily need to be orthogonal to each other. The length direction L, the width direction W, and the height direction T may intersect each other.

### Outer Shape of Multilayer Body

The multilayer body 2 has a substantially cuboid shape. The multilayer body 2 includes two main surfaces 3, two end surfaces 4, and two side surfaces 5. The main surfaces 3 are opposed to each other in the height direction T. The end surfaces 4 are opposed to each other in the length direction L. The side surfaces 5 are opposed to each other in the width direction W. One of the two main surfaces 3 is referred to as a first main surface 3a, and the other is referred to as a second main surface 3b. One of the two end surfaces 4 is referred to as a first end surface 4a, and the other is referred to as a second end surface 4b. One of the two side surfaces 5 is referred to as a first side surface 5a, and the other is referred to as a second side surface 5b. FIG. 7 depicts the second main surface 3b and the first side surface 5a.

A ridge line and a corner of the multilayer body 2 are preferably rounded. The ridge line is a portion of the multilayer body 2 at which two surfaces thereof meet. The corner is a portion of the multilayer body 2 at which three surfaces thereof meet. Note that the size of the multilayer body 2 is not particularly limited.

### External Electrodes

The external electrodes 20 provided on the multilayer body 2 include a first external electrode 20e, a second external electrode 20f, a third external electrode 20g, and a fourth external electrode 20h. The first external electrode 20e is provided primarily on the first end surface 4a of the multilayer body 2. The second external electrode 20f is provided primarily on the first side surface 5a of the multilayer body 2. The third external electrode 20g is provided primarily on the second side surface 5b of the multilayer body 2. The fourth external electrode 20h is provided primarily on the second end surface 4b of the multilayer body 2.

Specifically, the first external electrode 20e is continuously provided on the entirety of the first end surface 4a of the multilayer body 2 and on portions of the two main surfaces 3 and portions of the two side surfaces. The second external electrode 20f is continuously provided on a portion of the first side surface 5a and portions of the two main surfaces 3 of the multilayer body 2. As with the second external electrode 20f, the third external electrode 20g is continuously provided on a portion of the second side surface 5b and portions of the two main surfaces 3 of the multilayer body 2. As with the first external electrode 20e, the fourth external electrode 20h is continuously provided on the entirety of the second end surface 4b of the multilayer body 2 and on portions of the two main surfaces 3 and portions of the two side surfaces.

### Overview of Internal Electrodes

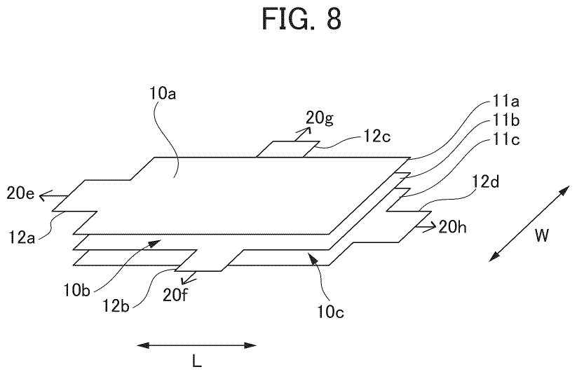

The multilayer body 2 includes a plurality of dielectric bodies 7 and a plurality of internal electrodes 10. The internal electrodes 10 included in the four-terminal multilayer ceramic capacitor 1c are described on the basis of FIG. 8. FIG. 8 illustrates at least portions of the internal electrodes 10 provided in the four-terminal multilayer ceramic capacitor 1c. The internal electrodes 10 include at least one layer of first internal electrode 10a, at least one layer of second internal electrode 10b, and at least one layer of third internal electrode 10c.

The first internal electrode 10a, the second internal electrode 10b, and the third internal electrode 10c are arranged in this order in the height direction T. FIG. 8 depicts internal electrodes 10 each defining one layer. This is only an example, and the configuration depicted in FIG. 8 may be repeated a plurality of times so as to provide a multilayer body.

### Overview of Lead-Out Sections of Internal Electrodes

The internal electrodes 10 each include a counter section 11 and a lead-out section 12. The counter section 11 is a portion of an internal electrode 10 that overlaps another internal electrode 10 when viewed from the height direction T. The lead-out section 12 is a portion led out from the counter section 11 in order to connect the internal electrode 10 to an external electrode 20. Thus, the counter section 11 is connected to the external electrode 20 via the lead-out section 12.

In particular, the first internal electrode 10a includes a first lead-out section 12a extending in the length direction L. A first counter section 11a of the first internal electrode 10a is connected to the first external electrode 20e via the first lead-out section 12a.

Likewise, the second internal electrode 10b includes a second lead-out section 12b and a third lead-out section 12c extending in the width direction W. A second counter section 11b of the second internal electrode 10b is connected to the second external electrode 20f via the second lead-out section 12b. A second counter section 11b of the second internal electrode 10b is connected to the third external electrode 20g via the third lead-out section 12c. In this way, the second internal electrode 10b is connected to two external electrodes 20 in the width direction W.

The third internal electrode 10c includes a fourth lead-out section 12d extending in the length direction L. A third counter section 11c of the third internal electrode 10c is connected to the fourth external electrode 20h via the fourth lead-out section 12d.

As described above, the internal electrodes 10 are each connected to corresponding one(s) of the four external electrodes 20. The four external electrodes 20 correspond to four terminals of the four-terminal multilayer ceramic capacitor 1c.

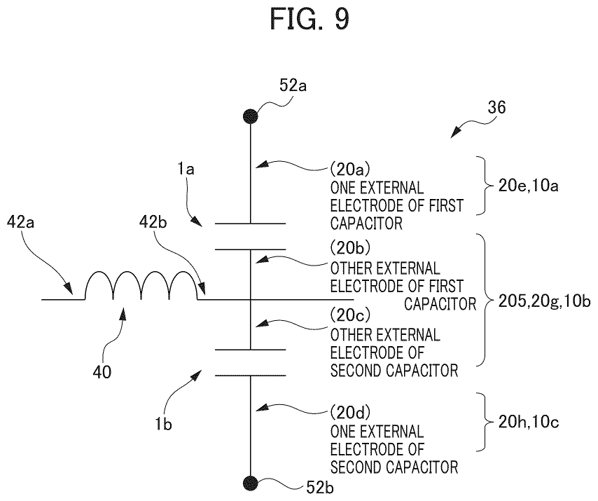

The following describes the relationship between the four-terminal multilayer ceramic capacitor 1c and the two capacitors 1 provided within the low-pass filter circuit 36. FIG. 9 illustrates the circuit configuration of the low-pass filter circuit 36. As described above, the first capacitor 1a and the second capacitor 1b included in the low-pass filter circuit 36 are defined by one four-terminal multilayer ceramic capacitor 1c.

The first capacitor 1a corresponds to a portion of the four-terminal multilayer ceramic capacitor 1c in which the first internal electrode 10a and the second internal electrode 10b are opposed to each other. The second capacitor 1b corresponds to a portion of the four-terminal multilayer ceramic capacitor 1c in which the second internal electrode 10b and the third internal electrode 10c are opposed to each other.

Accordingly, the external electrode (A)20a of the first capacitor 1a corresponds to the first external electrode 20e of the four-terminal multilayer ceramic capacitor 1c.

The external electrode (B)20b of the first capacitor 1a corresponds to the second external electrode 20f and the third external electrode 20g of the four-terminal multilayer ceramic capacitor 1c. Likewise, the external electrode (C)20c of the second capacitor 1b also corresponds to the second external electrode 20f and the third external electrode 20g of the four-terminal multilayer ceramic capacitor 1c. This is because the first capacitor 1a and the second capacitor 1b share the second internal electrode 10b.

The external electrode (D)20d of the second capacitor 1b corresponds to the fourth external electrode 20h of the four-terminal multilayer ceramic capacitor 1c.

To sum up, the four-terminal multilayer ceramic capacitor 1c includes a plurality of internal electrodes 10 and first to fourth external electrodes. The first external electrode 20e corresponds to one external electrode 20 of the first capacitor 1a that is connected to the first potential terminal 52a, i.e., corresponds to the external electrode (A)20a. The fourth external electrode 20h corresponds to one external electrode 20 of the second capacitor 1b that is connected to the second potential terminal 52b, i.e., corresponds to the external electrode (D)20d. The second external electrode 20f and the third external electrode 20g correspond to the other external electrode 20 of the first capacitor 1a, i.e., corresponds to the external electrode (B)20b. The second external electrode 20f and the third external electrode 20g also correspond to the other external electrode 20 of the second capacitor 1b, i.e., corresponds to the external electrode (C)20c.

The plurality of internal electrodes 10 include the first internal electrode 10a, which is connected to the first external electrode 20e. The plurality of internal electrodes 10 also include the second internal electrode 10b, which is opposed to the first internal electrode 10a with a dielectric body 7 therebetween and is connected to the second external electrode 20f and the third external electrode 20g. Furthermore, the plurality of internal electrodes 10 include the third internal electrode 10c, which is opposed to the second internal electrode 10b with a dielectric body 7 therebetween and is connected to the fourth external electrode 20h.

The following describes a cross section structure of the multilayer body 2 by referring to a cross-sectional view of the multilayer body 2.

### Internal Structure of Multilayer Body (LT Cross Section)

The internal structure of the multilayer body 2 is described on the basis of FIG. 10. FIG. 10 is a I-I line cross-sectional view of the four-terminal multilayer ceramic capacitor 1c depicted in FIG. 7. FIG. 10 depicts a LT cross section of the four-terminal multilayer ceramic capacitor 1c. The multilayer body 2 includes a plurality of dielectric bodies 7 and a plurality of internal electrodes 10. The plurality of dielectric bodies 7 and the plurality of internal electrodes 10 are stacked atop one another in the height direction T.

### Internal Electrodes

As described above, the internal electrodes 10 include a first internal electrode 10a, a second internal electrode 10b, and a third internal electrode 10c. In the LT cross section, the first counter section 11a of the first internal electrode 10a is connected via the first lead-out section 12a to the first external electrode 20e formed on the first end surface 4a. The third counter section 11c of the third internal electrode 10c is connected via the fourth lead-out section 12d to the fourth external electrode 20h formed on the second end surface 4b. In the LT cross section, the second internal electrode 10b is not connected to an external electrode 20. The second internal electrode 10b is connected to external electrodes 20 on the side surfaces 5.

### Internal Structure of Multilayer Body (WT Cross Section)

The internal structure of the multilayer body 2 is described on the basis of FIG. 11. FIG. 11 is a II-II line cross-sectional view of the four-terminal multilayer ceramic capacitor 1c depicted in FIG. 7. FIG. 11 depicts a WT cross section of the four-terminal multilayer ceramic capacitor 1c.

In the WT cross section, the second counter section 11b of the second internal electrode 10b is connected via the second lead-out section 12b to the second external electrode 20f formed on the first side surface 5a. The second counter section 11b of the second internal electrode 10b is connected via the third lead-out section 12c to the third external electrode 20g formed on the second side surface 5b. Thus, the second internal electrode 10b is connected to external electrodes 20 on both of the side surfaces 5. In the WT cross section, neither the first internal electrode 10a nor the third internal electrode 10c is connected to an external electrode 20. The first internal electrode 10a and the third internal electrode 10c are connected to external electrodes 20 on the end surfaces 4.

### Plane Structures (LW Cross Sections) of Internal Electrodes

Plane structures of the internal electrodes 10 are described on the basis of FIGS. 12-14. A plane structure is provided when an internal electrode 10 is viewed from the height direction T of the four-terminal multilayer ceramic capacitor 1c. FIGS. 12-14 are each a III-III line cross-sectional view of FIG. 7. FIGS. 12-14 each depict a LW cross section of the four-terminal multilayer ceramic capacitor 1c.

### First Internal Electrode

FIG. 12 depicts a plane structure of the first internal electrode 10a. The first counter section 11a of the first internal electrode 10a is connected via the first lead-out section 12a to the first external electrode 20e on the first end surface 4a. The length of the first lead-out section 12a in the width direction W is less than the length of the first counter section 11a in the width direction W. The first internal electrode 10a is not connected to any of the external electrodes 20 other than the first external electrode 20e.

### Second Internal Electrode

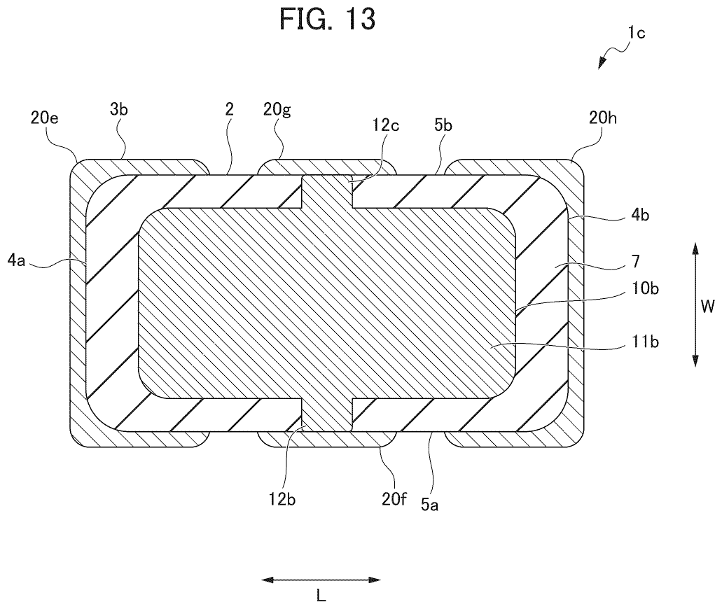

FIG. 13 depicts a plane structure of the second internal electrode 10b. The second counter section 11b of the second internal electrode 10b is connected via the second lead-out section 12b to the second external electrode 20f on the first side surface 5a. Meanwhile, the second counter section 11b of the second internal electrode 10b is connected via the third lead-out section 12c to the third external electrode 20g on the second side surface 5b. The length of the second lead-out section 12b in the length direction L and the length of the third lead-out section 12c in the length direction L are less than the length of the second counter section 11b in the length direction L. The second internal electrode 10b is not connected to any of the external electrodes 20 other than the second external electrode 20f and the third external electrode 20g.

### Third Internal Electrode

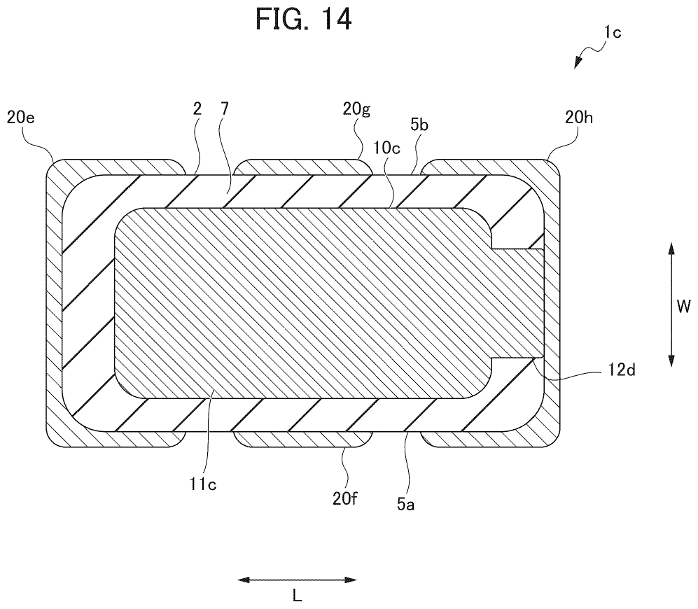

FIG. 14 depicts a plane structure of the third internal electrode 10c. The third counter section 11c of the third internal electrode 10c is connected via the fourth lead-out section 12d to the fourth external electrode 20h on the second end surface 4b. The length of the fourth lead-out section 12d in the width direction W is less than the length of the third counter section 11c in the width direction W. The third internal electrode 10c is not connected to any of the external electrodes 20 other than the fourth external electrode 20h.

### Number of Layers of Dielectric Bodies

For example, the number of layers of dielectric bodies 7 stacked in the multilayer body 2 may be 5 or larger and not larger than 2000.

### Thickness of Dielectric Body

For example, the thickness of the dielectric body 7 may 7 may be about 0.3 μm or greater and not greater than about 0.6 μm.

### Material for Dielectric Body

For example, a dielectric ceramic formed from a main component(s) such as BaTiO₃, CaTiO₃, SrTiO₃, and/or CaZrO₃ may be used as a material for the dielectric body 7. A material including these main components with an accessory component(s) such as a Mn compound, a Fe compound, a Cr compound, a Co compound, and/or a Ni compound added thereto may also be used.

### Number of Layers of Internal Electrodes

For example, the number of layers of internal electrodes 10 may be 10 or larger and not larger than 2000. Note that the number of layers of internal electrodes 10 includes the number of layers of first internal electrodes 10a and the number of layers of second internal electrodes 10b.

### Thickness of Internal Electrodes

For example, the thickness of the internal electrodes 10 may be about 0.1 μm or greater and not greater than about 5.0 μm, preferably, about 0.2 μm or greater and not greater than 2.0 μm.

### Material for Internal Electrodes

A material for the internal electrodes 10 may be, for example, a metal such as Ni, Cu, Ag, Pd, or Au, an alloy of Ni and Cu, or an alloy of Ag and Pd. In addition, the material for the internal electrodes 10 may include dielectric particles having the same composition system as the ceramic included in the dielectric bodies 7.

### Size of Multilayer Ceramic Capacitor

The size of the four-terminal multilayer ceramic capacitor 1c is not particularly limited. For example, the size of the four-terminal multilayer ceramic capacitor 1c may be as follows. The four-terminal multilayer ceramic capacitor 1c, including the multilayer body 2 and the external electrodes 20, has an L dimension in the length direction L. The L dimension is preferably about 0.25 mm or greater and not greater than about 1.0 mm, for example. The four-terminal multilayer ceramic capacitor 1c, including the multilayer body 2 and the external electrodes 20, has a T dimension in the height direction T. The T dimension is preferably about 0.125 mm or greater and not greater than about 0.5 mm, for example. The four-terminal multilayer ceramic capacitor 1c, including the multilayer body 2 and the external electrodes 20, has a W dimension in the width direction W. The W dimension is preferably about 0.125 mm or greater and not greater than about 0.5 mm, for example.

### Layer Configuration of External Electrodes

The external electrodes 20 may have a multi-layered structure. For example, when an external electrode 20 has a three-layer structure, the three layers may be a base layer, an inner plated layer, and an outer plated layer. For example, the base layer may be a fired layer of material containing a glass component and a metal. The inner plated layer may be a Ni-plated layer. The outer plated layer may be a Sn-plated layer.

### Method for Manufacturing Multilayer Ceramic Capacitor

The following describes a non-limiting example of a method for manufacturing the four-terminal multilayer ceramic capacitor 1c.

### Fabrication of Multilayer Block

Ceramic green sheets and an electrode paste for the internal electrodes 10 are prepared.

### Application of Paste

The electrode paste is applied to the ceramic green sheets in a desired pattern. For example, the electrode paste may be applied to the ceramic green sheets by using a method such as screen printing or gravure printing. In this way, the ceramic green sheets with the paste printed thereon, which are to be used for inner layer portions, are provided.

### Stacking

A prescribed number of ceramic green sheets on which is not printed a pattern for an internal electrode 10 are stacked. In this way, a portion corresponding to an outer layer portion is fabricated. Ceramic green sheets with the paste applied thereto for the inner layer portions are successively stacked on the portion corresponding to the outer layer portion. In this way, the portions corresponding to the inner layer portions are stacked. In addition, a prescribed number of ceramic green sheets for another outer layer portion are stacked on the structure. As a result, a multilayer sheet is fabricated. The multilayer sheet is pressed in the height direction via, for example, isostatic pressing, thereby fabricating a multilayer block.

### Fabrication of Multilayer Chip

The multilayer block is cut into a prescribed size so as to provide a multilayer chip. In this case, corners and ridge line portions of the multilayer chip may be rounded by, for example, barrel polishing.

### Firing

Next, the multilayer chip is fired so as to fabricate the multilayer body 2. The firing temperature depends on the materials for the dielectric bodies 7 and the internal electrodes 10 but is preferably about 900° C. or higher and not higher than about 1400° C., for example.

### External Electrodes

Next, the external electrodes 20 are formed. First, an electrically conductive paste to define base layers is applied at desired positions on the multilayer body 2 so as to form the base layers by performing firing treatment. Subsequently, a Ni-plated layer is formed on each base layer, and then a Sn-plated layer is formed on the Ni-plated layer. The Ni-plated layer defines an inner plated layer, and the Sn-plated layer defines an outer plated layer. In this way, the four-terminal multilayer ceramic capacitor 1c to be provided in the class D amplification circuit 30 can be fabricated.

### Second Example Embodiment

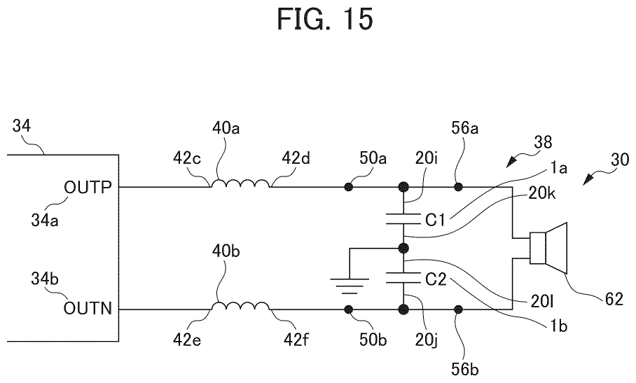

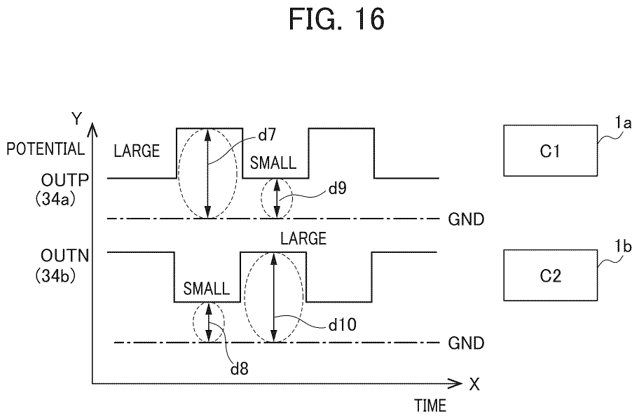

The following describes a second example embodiment of the present invention on the basis of FIGS. 15 and 16. FIG. 15 illustrates a class D amplification circuit according to the second example embodiment. FIG. 16 illustrates a potential difference and the like provided when a signal is input to a differential-signal filter circuit according to the second example embodiment. The following mainly describes differences from the first example embodiment. In the second example embodiment, a filter circuit including two capacitors 1 is used as a filter for a differential signal. In the following, components of a class D amplification circuit 30 according to the second example embodiment are sequentially described.

### Drive Circuits

The class D amplification circuit 30 according to the second example embodiment includes a PWM circuit (not illustrated), a first drive circuit 34a connected to the PWM circuit, a second drive circuit 34b connected to the PWM circuit, and a differential-signal filter circuit 38 connected to the first drive circuit 34a and the second drive circuit 34b. Thus, the class D amplification circuit 30 includes two drive circuits 34. The first drive circuit 34a is OUTP, and the second drive circuit 34b is OUTN.

### Differential-Signal Filter Circuit

The differential-signal filter circuit 38 includes two inductors 40 and two capacitors 1. The two inductors 40 are a first inductor 40a and a second inductor 40b. The two capacitors 1 are a first capacitor 1a and a second capacitor 1b. The first capacitor 1a and the second capacitor 1b each include a dielectric body 7 and internal electrodes 10 with the dielectric body 7 therebetween.

### Connection of Terminals

The differential-signal filter circuit 38 includes two input terminals 50 and two output terminals 56. Specifically, the differential-signal filter circuit 38 includes a first input terminal 50a, a second input terminal 50b, a first output terminal 56a, and a second output terminal 56b, and further includes a reference potential terminal 54. The first input terminal 50a is connected to the first drive circuit 34a. The second input terminal 50b is connected to the second drive circuit 34b. The reference potential terminal 54 is connected to a reference potential such as a ground. In addition, the first output terminal 56a and the second output terminal 56b are connected to a load circuit 62.

### Capacitors

Descriptions are given of the connection of the capacitors 1. One external electrode 20i of the first capacitor 1a is connected to the first input terminal 50a. One external electrode 20j of the second capacitor 1b is connected to the second input terminal 50b. Another external electrode 20k of the first capacitor 1a and another external electrode 20l of the second capacitor 1b are connected to the reference potential terminal 54.

### Inductors

Descriptions are given of the connection of the inductors 40. One external electrode 42d of the first inductor 40a, i.e., one of the two inductors 40, is connected to the first input terminal 50a. Another external electrode 42c of the first inductor 40a is connected to the first drive circuit 34a. One external electrode 42f of the second inductor 40b is connected to the second input terminal 50b. Another external electrode 42e of the second inductor 40b is connected to the second drive circuit 34b.

### Four-Terminal Multilayer Ceramic Capacitor

As in the case of the low-pass filter circuit 36 in the first example embodiment, the first capacitor 1a and the second capacitor 1b provided in the differential-signal filter circuit 38 are defined by one four-terminal multilayer ceramic capacitor 1c.

The class D amplification circuit 30 according to the second example embodiment can output an output signal having desired characteristics even when the voltage of a signal input to a capacitor 1 of the differential-signal filter circuit 38 changes. Descriptions are given in the following. FIG. 5 illustrates, for example, a voltage applied to each capacitor 1 when pulses are input to the class D amplification circuit 30 according to the present example embodiment. The X axis in FIG. 5 indicates time. The Y axis in FIG. 5 indicates potential.

When a pulse input to the first capacitor 1a of the differential-signal filter circuit 38 is Hi, the voltage applied to C1, i.e., the first capacitor 1a, is large (d7 in FIG. 16). By contrast, the voltage applied to C2, i.e., the second capacitor 1b, is small (d8 in FIG. 16). Thus, “capacitance decrease of C1>capacitance decrease of C2” is satisfied. Conversely, when a pulse input to the first capacitor 1a of the differential-signal filter circuit 38 is L, the voltage applied to C1, i.e., the first capacitor 1a, is small (d9 in FIG. 16). By contrast, the voltage applied to C2, i.e., the second capacitor 1b, is large (d10 in FIG. 16). Thus, “capacitance decrease of C2>capacitance decrease of C1” is satisfied.

In the differential-signal filter circuit 38 according to the present example embodiment, as described above, when the decrease in the capacitance of one capacitor from among C1 and C2 is large, the decrease in the capacitance of the other capacitor is small. This results in a reduction in the total capacitance of the entirety of the differential-signal filter circuit 38 which varies according to pulses. Thus, variations in the characteristics of the differential-signal filter circuit 38 are reduced. Accordingly, desired characteristics can be easily achieved for an output signal output to the first output terminal 56a and the second output terminal 56b.

As in the first example embodiment, various setting values pertaining to the class D amplification circuit 30 according to the second example embodiment can be set as appropriate. For example, examples of the setting values may be similar to those in the first example embodiment.

Although example embodiments of the present invention have been described so far, the present invention is not limited to the above-described example embodiments, and various changes and modifications can be made to the example embodiments.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A class D amplification circuit comprising:
a PWM circuit;
a drive circuit connected to the PWM circuit; and
a low-pass filter circuit connected to the drive circuit;
wherein
the low-pass filter circuit includes an inductor, a first capacitor, and a second capacitor;
the first capacitor and the second capacitor each include a dielectric body and electrodes with the dielectric body therebetween;
the low-pass filter circuit includes an input terminal, a first potential terminal, a second potential terminal, and an output terminal;
the input terminal is connected to the drive circuit;
the first potential terminal is connected to a first potential;
the second potential terminal is connected to a second potential that is lower than the first potential;
the output terminal is connected to a load circuit;
one external electrode of the first capacitor is connected to the first potential terminal;
one external electrode of the second capacitor is connected to the second potential terminal;
another external electrode of the first capacitor and another external electrode of the second capacitor are connected to the output terminal;
one external electrode of the inductor is connected to the input terminal; and
another external electrode of the inductor is connected to the output terminal.

2. The class D amplification circuit according to claim 1, wherein
the first capacitor and the second capacitor are defined by one four-terminal multilayer ceramic capacitor;
the four-terminal multilayer ceramic capacitor includes a plurality of internal electrodes and first to fourth external electrodes;
the first external electrode is the one external electrode of the first capacitor that is connected to the first potential terminal;
the fourth external electrode is the one external electrode of the second capacitor that is connected to the second potential terminal;
the second external electrode and the third external electrode are the another external electrode of the first capacitor, and are also the another external electrode of the second capacitor;
the plurality of internal electrodes include a first internal electrode connected to the first external electrode;
the plurality of internal electrodes include a second internal electrode opposed to the first internal electrode with the dielectric body therebetween and connected to the second external electrode and the third external electrode; and
the plurality of internal electrodes include a third internal electrode opposed to the second internal electrode with the dielectric body therebetween and connected to the fourth external electrode.

3. The class D amplification circuit according to claim 1, wherein the load circuit includes a speaker.

4. The class D amplification circuit according to claim 1, wherein a difference between a capacitance of the first capacitor and a capacitance of the second capacitor is within about ±50%.

5. The class D amplification circuit according to claim 2, wherein
the first external electrode and the fourth external electrode are on end surfaces of the four-terminal multilayer ceramic capacitor; and
the second external electrode and the third external electrode are on side surfaces of the four-terminal multilayer ceramic capacitor.

6. The class D amplification circuit according to claim 1, wherein the first capacitor and the second capacitor are a multilayer ceramic capacitor or a film capacitor.

7. The class D amplification circuit according to claim 1, wherein the first capacitor and the second capacitor define a lumped-constant circuit.

8. The class D amplification circuit according to claim 1, wherein the first capacitor and the second capacitor reduce influence from variation in an input voltage on an output signal.

9. The class D amplification circuit according to claim 1, wherein a capacitance ratio between the first capacitor and the second capacitor is about ±50%.

10. The class D amplification circuit according to claim 1, wherein a capacitance ratio between the first capacitor and the second capacitor is about ±10%.

11. A class D amplification circuit comprising:
a PWM circuit;
a first drive circuit connected to the PWM circuit;
a second drive circuit connected to the PWM circuit; and
a differential-signal filter circuit connected to the first drive circuit and the second drive circuit; wherein
the differential-signal filter circuit includes a first inductor, a second inductor, a first capacitor, and a second capacitor;
the first capacitor and the second capacitor each include a dielectric body and electrodes with the dielectric body therebetween;
the differential-signal filter circuit includes a first input terminal, a second input terminal, a first output terminal, a second output terminal, and a reference potential terminal;
the first input terminal is connected to the first drive circuit;
the second input terminal is connected to the second drive circuit;
the reference potential terminal is connected to a reference potential;
the first output terminal and the second output terminal are connected to a load circuit;
one external electrode of the first capacitor is connected to the first output terminal;
one external electrode of the second capacitor is connected to the second output terminal;
another external electrode of the first capacitor and another external electrode of the second capacitor are connected to the reference potential terminal;
one external electrode of the first inductor is connected to the first input terminal;
another external electrode of the first inductor is connected to the first drive circuit;
one external electrode of the second inductor is connected to the second input terminal; and
another external electrode of the second inductor is connected to the second drive circuit.

12. The class D amplification circuit according to claim 11, wherein
the first capacitor and the second capacitor are defined by one four-terminal multilayer ceramic capacitor,
the four-terminal multilayer ceramic capacitor includes a plurality of internal electrodes and first to fourth external electrodes;
the first external electrode is the one external electrode of the first capacitor that is connected to the first output terminal;
the fourth external electrode is the one external electrode of the second capacitor that is connected to the second output terminal;
the second external electrode and the third external electrode are the another external electrode of the first capacitor, and are also the another external electrode of the second capacitor;
the plurality of internal electrodes include a first internal electrode connected to the first external electrode;
the plurality of internal electrodes include a second internal electrode opposed to the first internal electrode with the dielectric body therebetween and connected to the second external electrode and the third external electrode; and
the plurality of internal electrodes include a third internal electrode opposed to the second internal electrode with the dielectric body therebetween and connected to the fourth external electrode.

13. The class D amplification circuit according to claim 11, wherein the load circuit includes a speaker.

14. The class D amplification circuit according to claim 11, wherein a difference between a capacitance of the first capacitor and a capacitance of the second capacitor is within about ±50%.

15. The class D amplification circuit according to claim 12, wherein
the first external electrode and the fourth external electrode are on end surfaces of the four-terminal multilayer ceramic capacitor; and
the second external electrode and the third external electrode are on side surfaces of the four-terminal multilayer ceramic capacitor.

16. The class D amplification circuit according to claim 11, wherein the first capacitor and the second capacitor are a multilayer ceramic capacitor or a film capacitor.

17. The class D amplification circuit according to claim 11, wherein the first capacitor and the second capacitor define a lumped-constant circuit.

18. The class D amplification circuit according to claim 11, wherein the first capacitor and the second capacitor reduce influence from variation in an input voltage on an output signal.

19. The class D amplification circuit according to claim 11, wherein a capacitance ratio between the first capacitor and the second capacitor is about ±50%.

20. The class D amplification circuit according to claim 11, wherein a capacitance ratio between the first capacitor and the second capacitor is about ±10%.
